(19) United States
(12) Patent Application Publication
(10) Pub. No.: US 2015/0295194 A1
(43) Pub. Date: Oct. 15, 2015

(54) LEAD-FREE SOLID-STATE ORGANIC-INORGANIC HALIDE PEROVSKITE PHOTOVOLTAIC CELLS

(71) Applicant: Northwestern University, Evanston, IL (US)

(72) Inventors: Mercouri G. Kanatzidis, Wilmette, IL (US); Feng Hao, Evanston, IL (US)

(21) Appl. No.: 14/686,539

(22) Filed: Apr. 14, 2015

Related U.S. Application Data
(60) Provisional application No. 61/979,673, filed on Apr. 15, 2014.

(51) Int. Cl. H01L 51/42

(52) U.S. Cl. CPC H01L 51/4253

(57) ABSTRACT

Photoactive materials comprising semiconducting organic-inorganic tin halide perovskite compounds for use in the light absorbing layers of photovoltaic cells are provided. Photovoltaic cells incorporating the photoactive materials into their light-absorbing layers are also provided.

### CROSS-REFERENCE TO RELATED APPLICATIONS

The present application claims priority to U.S. Provisional Patent Application No. 61/979,673 that was filed Apr. 15, 2014, the entire contents of which are hereby incorporated by reference.

### REFERENCE TO GOVERNMENT RIGHTS

This invention was made with government support under DE-SC0001059 awarded by the Department of Energy. The government has certain rights in the invention.

### BACKGROUND

The development of clean alternatives to current power generation methods is immensely important to preserve the global environment and assure sustained economic growth¹. The recent emergence of halide perovskites as light harvesters and hole transport materials has revolutionized the scenario of emerging photovoltaic technologies²⁻¹⁴. Organic-inorganic hybrid perovskite compounds based on metal halides adopt the ABX₃ perovskite structure. This structure consists of a network of corner-sharing BX₆ octahedra, where the B atom is a metal cation (typically Sn²⁺ or Pb²⁺) and X is typically F⁻, Cl⁻, Br⁻, or I⁻; the A cation is selected to balance the total charge and it can even be a Cs⁺ or a small molecular species¹⁵⁻¹⁷. Recent implementation of CH₃NH₃PbX₃ (X=I, Cl, Br) perovskite absorbers with the organic hole conductor 2,2′,7,7′-tetrakis-(N,N-di-p-methoxyphenylamine)9,9′-spirobifluorene (spiro-OMeTAD) enabled power conversion efficiencies of 12-15%^{8,18}, which has been recognized as the “Next Big Thing in Photovoltaics”¹⁹⁻²². A planar heterojunction photovoltaic device incorporating vapor-deposited perovskite (CH₃NH₃PbI₃₋ₓClₓ) as the absorbing layer showed overall power conversion efficiencies of over 15% with a high open-circuit voltage up to 1.07 V, further highlighting the industrial application potential in the near future′. Recent studies indicate the mixed-halide organic-inorganic hybrid perovskites can display electron-hole diffusion lengths over 1 micrometer, which is consistent with reports of very high carrier mobilities in these materials²³ and supports expectations for highly efficient and cheap solar cells using thick absorption layers^{24,25}. However, to realize commercial applications of this technology it is important to reach analogous optical and photovoltaic performance using lead-free organic-inorganic compounds.

### SUMMARY

Photoactive materials comprising semiconducting organic-inorganic tin halide perovskite compounds for use in the light absorbing layers of photovoltaic cells are provided. Photovoltaic cells incorporating the photoactive materials into their light-absorbing layers are also provided.

One embodiment of a photovoltaic cell comprises: (a) a first electrode comprising an electrically conductive material; (b) a second electrode comprising an electrically conductive material; (c) a photoactive material disposed between, and in electrical communication with, the first and second electrodes, the photoactive material comprising an organic-inorganic tin halide perovskite compound; and (d) a hole transporting material disposed between the first and second electrodes and configured to facilitate the transport of holes generated in the photoactive material to one of the first and second electrodes.

In some embodiments, the organic-inorganic tin halide perovskite compound has the formula CH₃NH₃SnI₃₋ₓBrₓ, wherein x is in the range from 0 to 3. In some embodiments, of the photovoltaic cells the hole transport material is doped with a pyridine derivative, such 2,6-lutidine. One example of a suitable hole transport materials is (2,2′,7,7′-tetrakis(N,N-di-p-methoxyphenylamine)-9,9-spirobifluorene).

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1A. Perovskite crystal structure of a CH₃NH₃SnI₃₋ₓBrₓ absorber material.

FIG. 1B. Experimental and simulated X-ray diffraction pattern for the CH₃NH₃SnI₃.

FIG. 1C. Optical absorption and photoluminescence spectra for the CH₃NH₃SnI₃.

FIG. 1D. Conductivity and Seebeck coefficient as a function of the temperature for a sample of CH₃NH₃SnI₃ prepared from the solution method as described in the Example.

FIG. 2. A representative cross sectional SEM view of a completed photovoltaic device incorporating a CH₃NH₃SnI₃ perovskite. Each layer is indicated on the left. The scale bar represents 200 nm.

FIG. 3A. X-ray diffraction patterns of a CH₃NH₃SnI₃₋ₓBrₓ perovskite.

FIG. 3B. Absorption spectra of CH₃NH₃SnI₃₋ₓBrₓ (x=0, 1, 2, 3) perovskites.

FIG. 3C. Schematic energy level diagram of the CH₃NH₃SnI₃₋ₓBrₓ with TiO₂ and spiro-MeOTAD hole transporting material. The valence band maxima (E_{CB}) of the methylammonium tin halides were extracted from ultraviolet photoelectron spectroscopy (UPS) measurements under high vacuum.

FIG. 4A. Photocurrent density-voltage (J-V) characteristics for devices incorporating CH₃NH₃SnI₃₋ₓBrₓ perovskites.

FIG. 4B. Corresponding incident-photon-conversion-efficiency (IPCE) spectra of devices based on CH₃NH₃SnI₃₋ₓBrₓ (x=0, 1, 2, 3) perovskites.

FIG. 5. Thermal gravimetric analysis (TGA) of commercial, as-synthesized and purified SnI₂. As indicated in the TG curves, the SnI₂ easily gets oxidatized to SnI₄ even exposed in air, corresponding to a sharp weight loss happening around 150° C. The latter weight loss can be indexed to the melting of SnI₂ itself. After purification, the Sn⁴⁺ impurity can be efficiently removed.

FIG. 6. Ultraviolet photoelectron spectrum of the synthesized CH₃NH₃SnI₃. The binding energy is calibrated with respect to He I photon energy (21.21 eV). The valence band energy can be estimated to be ˜−5.47 eV below vacuum level.

### DETAILED DESCRIPTION

Photoactive materials (that is—materials that are capable of absorbing radiation and generating an electron-hole pair) comprising semiconducting organic-inorganic tin halide perovskite compounds for use in the light absorbing layers of photovoltaic cells are provided. Photovoltaic cells incorporating the photoactive materials into their light-absorbing layers are also provided.

The organic-inorganic tin halide perovskites have the general formula ASnX₃, wherein A is a monovalent organic cation, examples of which include methylammonium (CH₃NH₃⁺), formamidinium (HC(NH)₂)₂⁺), methylformamidinium (H₃CC(NH)₂)₂⁺) and guanidinium (C(NH)₂)₃⁺), and X represents one or more halides. For example, X may be an iodide, a bromide or a mixed iodide/bromide halide. In some embodiments, the organic-inorganic tin halide perovskite compound has the formula CH₃NH₃SnI₃₋ₓBrₓ, wherein x is in the range from 0 to 3. In some such embodiments 0<x<3.

In some embodiments, the hole transport materials further comprise a dopant that serves to increase the hole mobility in the material. Suitable dopants include pyridine derivatives, such as di-substituted pyridine derivatives. By way of illustration, the dopants can be 2,6-dialkyl derivatives, where the alkyl group can be, for example, a C₁ to C₁₀ alkyl group, such as a methyl, ethyl, or propyl group; benzo-substituted pyridines such as quinolones and acridines; and derivatives thereof 2,6-lutidine is an example of a suitable 2,6-dialkyl derivative. The use of 2,6-lutidine is advantageous because it does not degrade CH₃NH₃SnI₃₋ₓBrₓ, as does tributyl-pyridine. In some embodiment the hole transport materials are free of tirbutyl-pyridine and derivatives thereof.

Photovoltaic cells incorporating the organic-inorganic tin halide perovskite compounds as a photoactive material can take on a variety of forms. Generally, however, the cells will comprises a first electrode comprising an electrically conductive material, a second electrode comprising an electrically conductive material, a light absorbing layer comprising the organic-inorganic tin halide perovskite compounds disposed between (including partially between) and in electrical communication with the first and second electrodes, and an organic hole transporting material disposed between (including partially between) the first and second electrodes and configured to facilitate the transport of holes (that is, to provide preferential transport of holes relative to electrons) generated in the light absorbing layer to one of the first or second electrodes. In some cells the photoactive material takes the form of a porous film (e.g., a film comprising a collection of semiconducting nanoparticles, such as titanium dioxide nanoparticles) coated with the organic-inorganic tin halide perovskites, wherein the coating infiltrates into the pores of the porous film. Other layers commonly used in thin film photovoltaic cells, such as electron transport layers, hole blocking layers and the like, may also be incorporated into the present photovoltaic cells.

Triarylamine derivatives, such as spiro-MeOTAD (2,2′,7,7′-tetrakis(N,N-di-p-methoxyphenylamine)-9,9-spirobifluorene), are examples of suitable organic hole transport materials for use in the present photovoltaic cells.

At least one of the two electrodes is desirably transparent to the incident radiation (e.g., solar radiation). The transparent nature of the electrode can be accomplished by constructing the electrode from a transparent material or by using an electrode that does not completely cover the incident surface of the cell (e.g., a patterned electrode). One example of a transparent electrode comprises a transparent conducting oxide (e.g., fluorine-doped tin oxide (FTO)) coating on a transparent substrate.

The organic-inorganic tin halide perovskite compounds are characterized by broad and tunable absorption spectra. For example, some embodiments of the organic-inorganic tin halide perovskite compounds have an absorption of at least 60% through the wavelength range between about 600 and about 800 nm. The absorption spectra for the organic-inorganic tin halide perovskite compounds can be tuned by adjusting the ratio of the halides in mixed halide compounds. For example, various embodiments of the compounds have absorption onsets in the ranges from about 570 to about 950 nm, as illustrated in the Example.

Photovoltaic cells comprising light-absorbing layers formed from the organic-inorganic tin halide perovskite compounds can have high power conversion efficiencies. For example, photovoltaic cells having conversion efficiencies under simulated full sunlight of 100 mW cm⁻² of at least 4, at least 5 and at least 5.8% are provided. These power conversion efficiencies can be obtained using very thin light-absorbing layers of 500 nm or less. Methods for determining the power conversion efficiency of a solar cell are provided in the Example.

### Example

This example illustrates the use of a lead-free perovskite of methylammonium tin iodide (CH₃NH₃SnI₃) as the light absorbing material in solution-processed solid-state photovoltaic devices. Featuring an optical band gap of 1.3 eV, the CH₃NH₃SnI₃ is used in conjunction with an organic spiro-OMeTAD hole transport layer to provide an unprecedented absorption onset up to 950 nm. Further chemical alloying of iodide with bromide provides efficient energetic tuning of the band structure of the perovskites, leading to a power conversion efficiency of 5.8% under simulated full sunlight of 100 mW cm².

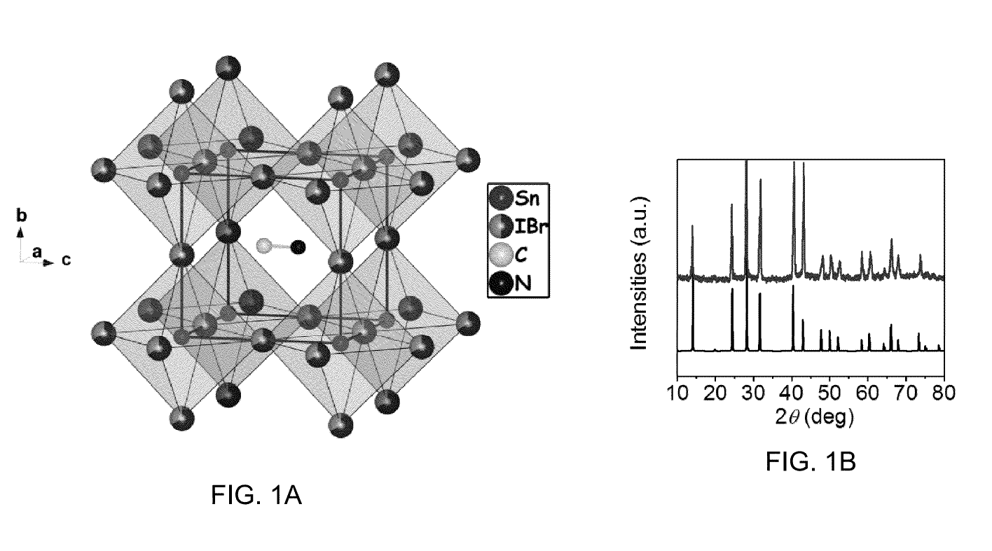

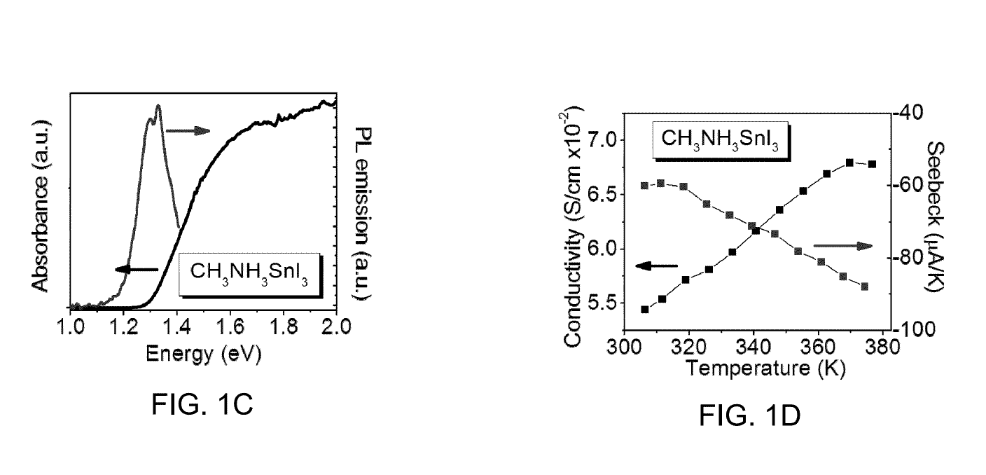

As shown in FIGS. 1A and B, CH₃NH₃SnI₃ adopts the perovskite structure type, crystallizing in the pseudocubic space group P4 mm at ambient conditions. Unlike the CH₃NH₃PbI₃, which has a lower symmetry at room temperature (β-phase), the Sn-analogue adopts its highest symmetry phase (α-phase) already at room temperature. The corner-sharing [SnI₆]⁴⁻ polyhedra form an infinite three-dimensional lattice with Sn—I—Sn connecting angles being 177.43(1)° and 180°, for the a- and c-axis, respectively. The deviation from the ideal cubic (Pm-3m) structure arises from orientational polarization of the CH₃NH₃⁻ cation along the C—N bond direction which is imposed to the three dimensional [SnI₃]⁻ inorganic lattice coinciding with the crystallographic c-axis²³.

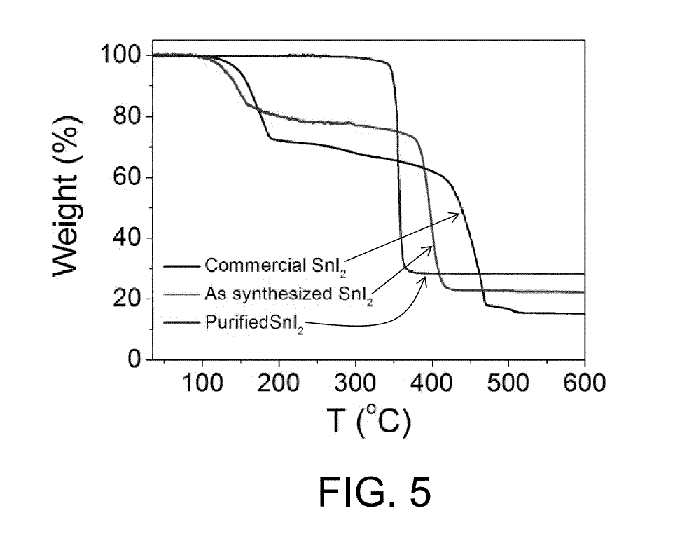

CH₃NH₃SnI₃ is a direct gap semiconductor with an energy gap of 1.3 eV as shown experimentally and theoretically^{23,26}. The optical band gap (E_{g}) of the CH₃NH₃SnI₃ compound (determined from diffuse reflectance measurements) is shown in FIG. 1C. The optical absorption coefficient (α/S) is calculated using reflectance data according to the Kubelka-Munk equation²⁷, α/S=(1−R)²/2R, where R is the percentage of reflected light. At room temperature, the material displays a strong photoluminescence (PL) emission at 950 nm which corresponds to the onset of the absorption edge (FIG. 1C). The PL intensity can act as a qualitative measure of the number of photogenerated carriers' efficiency in semiconductors²⁸. As depicted in FIG. 1D, its bulk electrical conductivity (σ) is −5-10⁻² S/cm at room temperature corresponding to a Seebeck coefficient (S) of ˜−60 μV/K (n-type). The compound has a low carrier concentration on the order of ˜10¹⁴ cm⁻³ and high electron mobilities (μₑ) on the order of ˜2000 cm²/V·s, which is comparable or even superior to most traditional semiconductors such as Si, CuInSe₂, and CdTe, with comparable band gap energy. The doping level of CH₃NH₃SnI₃ can be varied greatly depending on the preparation method. Carrier concentrations of up to 10¹⁹ cm⁻³ have been reported for CH₃NH₃SnI₃²⁹, showing a strong p-type character and a metallic behavior suggesting a heavily doped semiconducting behavior. This large difference in the transport properties can be attributed to Sn⁴ impurities that are inherently present in commercial SnI₂ and readily detectable by a mass loss at ˜150° C. in thermal gravimetric analysis (TGA) (as shown in FIG. 5). Therefore, in making the solar cells care must be taken in depositing films of the tin perovskite with low carrier concentration.

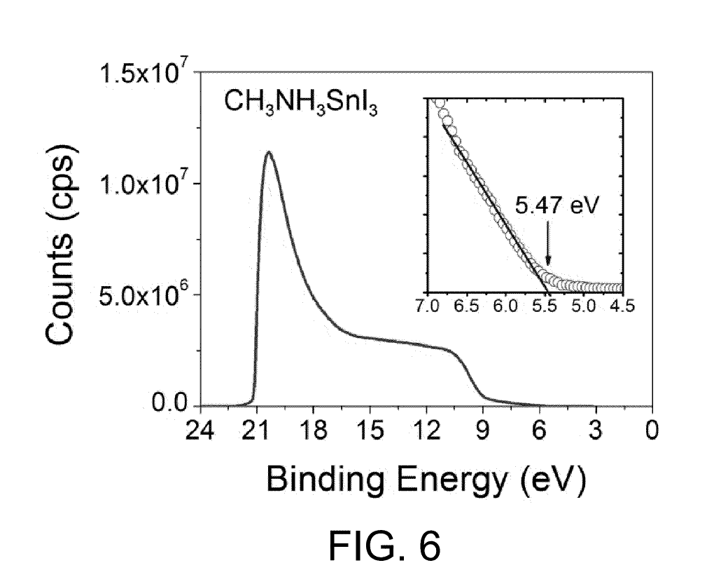

The valence band maximum (E_{VB}) of the CH₃NH₃SnI₃ compound was determined from ultraviolet photoelectron spectroscopy (UPS) measurements. The UPS spectrum for the CH₃NH₃SnI₃ is shown in (FIG. 6), where the energy is calibrated with respect to He I photon energy (21.21 eV). The valence band energy (E_{VB}) is estimated to be ˜−5.47 eV below vacuum level, which is close to the reported value for CH₃NH₃PbI₃ (−5.43 eV)⁵. From the observed optical band gap, the conduction band energy (E_{CB}) of CH₃NH₃SnI₃ was determined to be at ˜−4.17 eV. That is slightly higher than the E_{CB} for the TiO₂ anatase electrode (−4.26 eV)⁵.

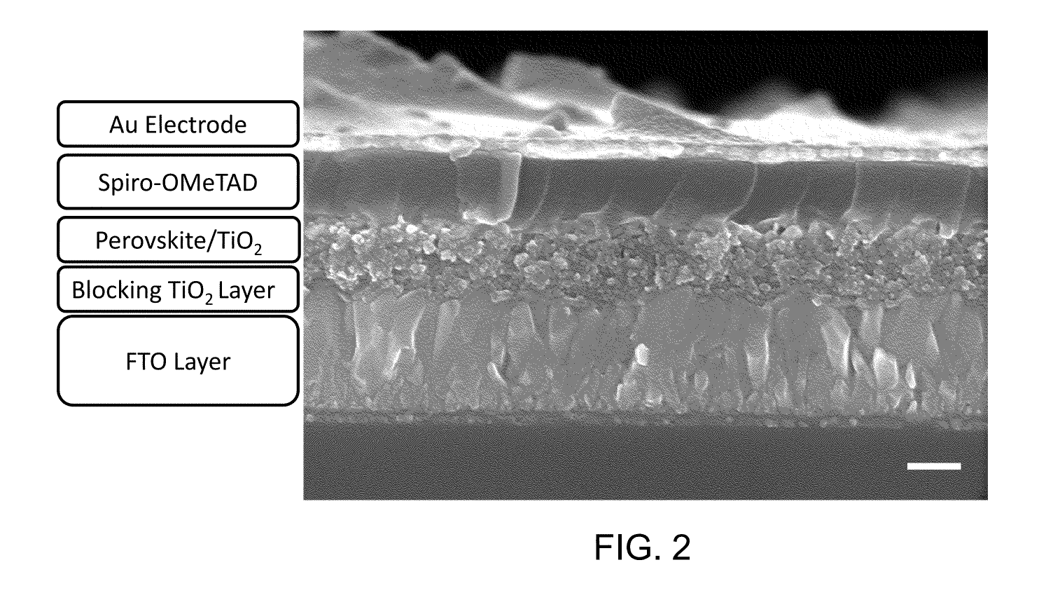

To fabricate the solid-state solar cells, mesoporous anatase TiO₂ films were prepared by spin-coating a solution of colloidal anatase particles of 20 nm in size onto a 30-nm-thick compact TiO₂ underlayer³⁰. The underlayer was deposited by atomic layer deposition on a pre-patterned transparent-conducting-oxide-coated glass substrate acting as the electric front contact of the solar cell. Deposition of the perovskite light absorbing layer was carried out by spin coating in a nitrogen glove box to avoid hydrolysis and oxidation of the tin perovskite in contact with air. The triarylamine derivative 2,2′,7,7′-tetrakis-(N,N-di-p-methoxyphenylamine)-9,9′-spirobifluorene (spiro-MeOTAD)³¹ was then applied as a hole-transporting material (HTM) on top of the mesoporous TiO₂ and perovskite layer. Lithium bis(trifluoromethylsulphonyl)imide and 2-6-dimethylpyridine (lutidine) were added in the HTM solution as dopants to increase the hole mobility³¹. FIG. 2 shows a representative cross-sectional SEM image of a typical solar cell device. The mesoporous TiO₂ film showed an average thickness of ˜350 nm and was infiltrated with the perovskite nanocrystals using the spin-coating procedure. The HTM penetrates into the remaining pore volume of the perovskite/TiO₂ layer and forms a 200-nm-thick capping layer on top of the composite structure. A thin gold layer was thermally evaporated under high vacuum onto the HTM layer, forming the back contact electrode of the device.

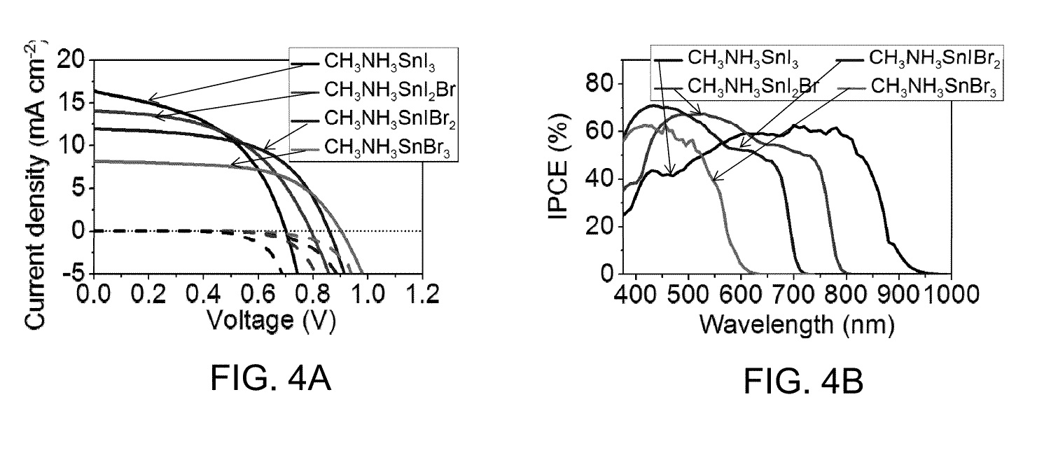

The solid state device based on the CH₃NH₃SnI₃ perovskite shows a high short-circuit photocurrent density (J_{sc}) of 16.34 mA cm², an open-circuit voltage (V_{oc}) of 0.70 V and a moderate fill factor (FF) of 0.47 under AM1.5G solar illumination, corresponding to a power conversion efficiency (PCE) of 5.38% (FIG. 4A). This high current density was achieved with submicron thick TiO₂ films (i.e. 350 nm) due to the large optical absorption cross section of the perovskite material and the well-developed interfacial pore filling by the hole conductor as can be seen in FIG. 2. More importantly, the incident photon-to-electron conversion efficiency (IPCE) of the CH₃NH₃SnI₃-based device covers the entire visible spectrum and reaches a broad absorption maximum of over 60% from 600 to 850 nm. It is accompanied with a notable absorption onset up to 950 nm (FIG. 4B), which is in good agreement with the optical band gap of ˜1.30 eV. Integrating the overlap of the IPCE spectrum with the AM1.5G solar photon flux yields a current density of 16.60 mA cm⁻², which is in excellent agreement with the measured photocurrent density. This confirms that any mismatch between the simulated sunlight and the AM1.5G standard is negligibly small.

It has been recently observed that the charge accumulates in high density in the perovskite absorber material instead of the semiconducting TiO₂, making this type of photovoltaic device fundamentally different from dye-sensitized solar cells³². Thus, the V_{oc} in a perovskite solar cell is more correlated with the energy difference between the HTM potential and the conduction band edge of the perovskite itself, rather than the TiO₂ conduction band edge. From the above-mentioned band alignment it can be inferred that the conduction band edge (E_{CB}) of CH₃NH₃SnI₃ is ˜0.24 eV lower than in CH₃NH₃PbI₃, thus leading to a lower V_{oc} for the CH₃NH₃SnI₃ perovskite device. Therefore, in an attempt to increase the V_{oc} of these lead-free devices, chemical substitution of the iodide atom with bromide was applied in order to favorably tune the band gap energetics³³.

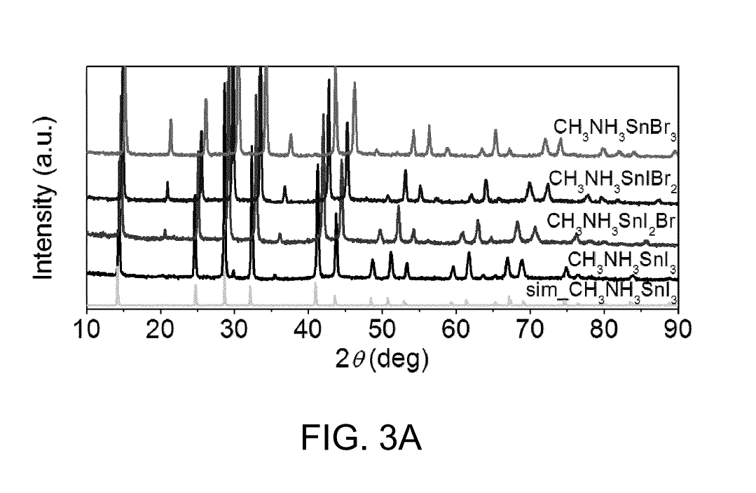

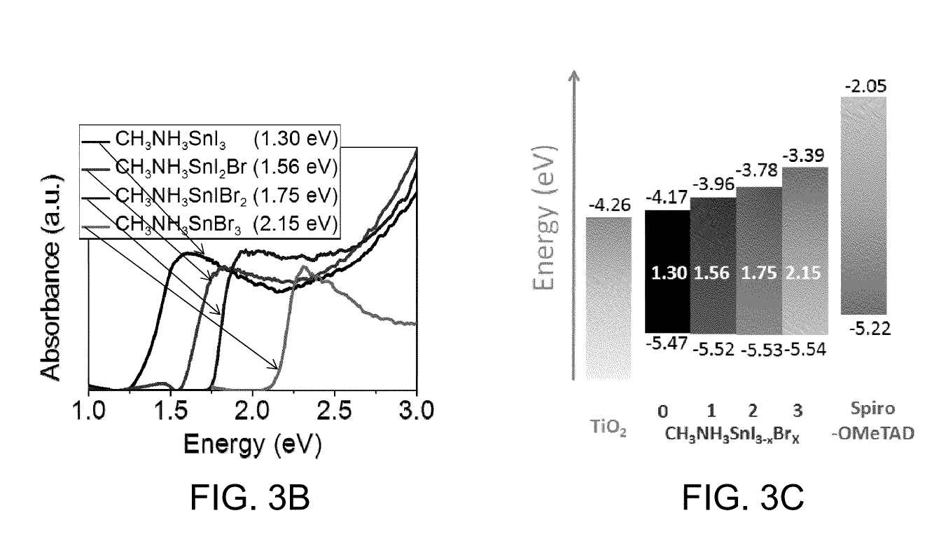

The CH₃NH₃SnI₃₋ₓBrₓ compounds were prepared by mixing stoichiometric amounts of CH₃NH₃X and SnX₂, (X=Br, I) finely homogenized in a mortar in the nitrogen glove box. The resulting solids were sealed in silica ampules under 10⁻⁴ mbar vacuum and heated up to 200° C. to complete the reaction. As shown by the XRD patterns in FIG. 3A, this series of compositions forms a continuous solid solution throughout the composition range without displaying any structural transitions (at room temperature), thus retaining the crystal structure of both end members, crystallizing at the P4 mm space group. The properties of the solid solutions are clearly displayed by a continuous contraction of the lattice parameters from the CH₃NH₃SnI₃ to CH₃NH₃SnBr₃ end members which results in a remarkable widening of the band gap, Table 1.

TABLE 1
Optical band gaps and refined lattice parameters of the CH₃NH₃SnI₃₋ₓBrₓ
(x = 0, 1, 2, 3) perovskites and corresponding solar cell performance parameters.

| | E_{g} | Lattice parameters | J_{sc} | J_{cal} | V_{oc} | | PCE | Rₛ |
|---|---|---|---|---|---|---|---|---|
| Perovskites | (eV) | (Å) | (mA cm⁻²) | (mA cm⁻²) | (V) | FF | (%) | (Ω) |
| CH₃NH₃SnI₃ | 1.30 | a = 6.169(1) | 16.34 | 16.60 | 0.70 | 0.47 | 5.38 | 352.58 |
| | | c = 6.173(4) | | | | | | |
| CH₃NH₃SnI₂Br | 1.56 | a = 6.041(1) | 14.06 | 13.96 | 0.79 | 0.50 | 5.52 | 105.00 |
| | | c = 6.053(4) | | | | | | |
| CH₃NH₃SnIBr₂ | 1.75 | a = 5.948(1) | 11.96 | 11.73 | 0.86 | 0.57 | 5.84 | 65.24 |
| | | c = 5.953(4) | | | | | | |
| CH₃NH₃SnBr₃ | 2.15 | a = 5.837(1) | 8.15 | 7.93 | 0.90 | 0.60 | 4.41 | 60.98 |
| | | c = 5.853(4) | | | | | | |

To check the optical properties in the hybrid halide perovskite, the UV-visible diffuse reflectance spectra of CH₃NH₃SnI₃₋ₓBrₓ (x=0, 1, 2, 3) were measured and transformed to absorption spectra as mentioned above. FIG. 3B shows that the absorption onset of CH₃NH₃SnI₃₋ₓBrₓ (x=0, 1, 2, 3) hybrid halide perovskites can be tuned from 954 nm (1.30 eV for CH₃NH₃SnI₃) to 577 nm (2.15 eV for CH₃NH₃SnBr₃), thus resulting in significant color tunability for perovskite photovoltaic devices. The intermediate iodide/bromide hybrid perovskites of CH₃NH₃SnI₂Br and CH₃NH₃SnIBr₂ show an absorption onset of 795 nm (1.56 eV) and 708 nm (1.75 eV), respectively. The valence band energy (E_{VB}) of the CH₃NH₃SnI₃₋ₓBrₓ compounds was also estimated from the UPS measurements. As illustrated in FIG. 3C, the E_{CB} raised up from −4.17 eV below the vacuum level for CH₃NH₃SnI₃ to −3.96 eV for CH₃NH₃SnI₂Br and −3.78 eV for CH₃NH₃SnIBr₂, and finally to −3.39 eV of CH₃NH₃SnBr₃. It is obvious from the band alignment that the change in the band gap (E_{g}) is mainly due to the conduction band (CB) shift to higher energy while the valence band (VB) energy remains practically unchanged. This trend allows for band gap engineering and the tuning of energetics for more efficient solar cell architectures.

FIGS. 4A and 4B present the representative photocurrent density-voltage (J-V) characteristics and incident-photon-conversion-efficiency (IPCE) spectra for devices constructed with the CH₃NH₃SnI₃₋ₓBrₓ perovskites as light harvesters. The photovoltaic parameters are summarized in Table 1. Through the chemical compositional control of CH₃NH₃SnI₃₋ₓBrₓ, the corresponding device color can be tuned from black for CH₃NH₃SnI₃ to dark brown for CH₃NH₃SnI₂Br and to yellow for CH₃NH₃SnBr₃ with increasing Br content. Notably, J_{sc} decreased from 16.34 mA cm² for CH₃NH₃SnI₃ to 8.15 mA cm⁻² for CH₃NH₃SnBr₃ with increasing Br content, whereas V_{oc} increased from 0.70 to 0.90 V when switching from the pure iodide to pure bromide perovskite. In addition to the significant improvement in V_{oc}, an increase in FF from 0.47 to 0.60 was also observed upon the incorporation of the Br ions. Amongst the investigated CH₃NH₃SnI₃₋ₓBrₓ perovskites, the device with CH₃NH₃SnIBr₂ delivered the highest PCE of 5.84% with a J_{sc} of 11.96 mA cm⁻², a V_{oc} of 0.856 V, together with a FF of 0.57. The reduction of J_{sc} with increasing Br content is directly related with the blue shift of absorption onset, as indicated from the IPCE spectra in FIG. 4B. Consistent with the band gap tuning, the onset of the IPCE spectra blue shifted from 950 nm for the iodide perovskite to ˜600 nm for the pure bromide perovskite. Integrating the overlap of these IPCE spectra with the AM1.5G solar photon flux yields similar current density (J_{cal}) with the measured photocurrent density (J_{sc}), as tabulated in Table 1. The improvement of V_{oc} can be attributed to the raised conduction band edge (E_{CB}) with increasing Br content in CH₃NH₃SnI₃₋ₓBrₓ. However, the FF is significantly lower than the reported values for high-efficient perovskite solar cells^{7,8,18}. It is well recognized that the FF of solar cells is primarily dominated by the series resistance (Rₛ), which mainly comes from three factors: (1) the active and interfacial layer resistances, (2) electrode resistance, and (3) the contact resistance. In the current work, Rₛ among the cells with CH₃NH₃SnI₃₋ₓBrₓ perovskites will be mainly caused by the difference of the active layer resistance, since factors (2) and (3) will be similar due to being common in all of the devices. Rₛ was estimated from the slope of the J-V curve at the open-circuit voltage point. As shown in Table 1, the Rₛ value decreased from 352.58Ω for a device with CH₃NH₃SnI₃ to 60.98Ω for CH₃NH₃SnBr₃, which is in accordance with the observed FF enhancement from 0.47 to 0.60.

Remarkably, the solid solutions and the CH₃NH₃SnBr₃ end-member display no PL emission at room temperature in the bulk form or after deposition on the TiO₂ film. This behavior suggests that the lifetime of the photogenerated electron-hole pairs is significantly longer in the solid solutions compared to the CH₃NH₃SnI₃ end-member which is beneficial for improving the charge collection efficiency. This trend also suggests that the relatively low FF for CH₃NH₃SnI₃ can be attributed to radiative carrier recombination most likely originating from Sn²⁺/Sn⁴⁺ defects. The defects are particularly stable in CH₃NH₃SnI₃; however bromide incorporation in the structure of CH₃NH₃SnI₃₋ₓBrₓ destabilizes the defects leading to total quenching of the PL emission, thereby improving the materials' performance by blocking the radiative recombination pathway. This type of chemical alloying represents a general approach for tuning and optimizing the performance of perovskite solar cells.

In summary, the methylammonium tin halide perovskites (CH₃NH₃SnI₃₋ₓBrₓ) were employed as lead-free light harvesters for solar cell applications. Featuring an ideal optical band gap of 1.3 eV, devices with CH₃NH₃SnI₃ perovskite together with an organic spiro-OMeTAD hole transport layer showed a notable absorption onset up to 950 nm, which is significant red-shifted compared with the benchmark CH₃NH₃PbI₃ counterpart (1.55 eV). The band gap engineering of CH₃NH₃SnI₃₋ₓBrₓ perovskites can be controllably tuned to cover almost the entire visible spectrum, thus enabling the realization of lead-free, colorful solar cells and leading to a promising initial power conversion efficiency of 5.8% under simulated full sunlight.

Methods

Materials.

Unless stated otherwise, all materials were purchased from Sigma-Aldrich and used as received. Spiro-MeOTAD was purchased from Merck KGaA. CH₃NH₃I, CH₃NH₃Br and SnI₂ were synthesized and purified according to a reported procedure²³. CH₃NH₃SnI₃₋ₓBrₓ compounds were prepared by mixing stoichiometric amounts of CH₃NH₃X and SnX₂, (X=Br, I) finely homogenized in a mortar in a nitrogen glove box. The resulting solids were sealed in quartz ampules under 10⁻⁴ mbar vacuum and heated up to 200° C. to complete the reaction²³.

Material Characterization.

Optical diffuse-reflectance measurements were performed at room temperature using a Shimadzu UV-3101 PC double-beam, double-monochromator spectrophotometer operating from 200 to 2500 nm. BaSO₄ was used as a non-absorbing reflectance reference. PL spectrum were measured using an OmniPV Photoluminescence system, equipped with a DPSS frequency-doubling Nd:YAG laser (500 mW power output, class 4) emitting at 532 nm, coupled with a bundle of 8 400 μm-core optical fibers as an excitation source. Resistivity measurements were made for arbitrary current directions in the ab-plane using standard point contact geometry. A homemade resistivity apparatus equipped with a Keithley 2182A nanovoltometer, Keithley 617 electrometer, Keithley 6220 Precision direct current (DC) source, and a high temperature vacuum chamber controlled by a K-20 MMR system was used. Seebeck measurements were performed on the same homemade apparatus using Cr/Cr:Ni thermocouples as electric leads that were attached to the sample surface by means of colloidal graphite isopropanol suspension. The temperature gradient along the crystal was generated by a resistor on the “hot” side of the crystal. The data were corrected for the thermocouple contribution using a copper wire.

Device Fabrication.

FTO-coated glass substrates (Tec15, Hartford Glass Co. Inc.) were patterned by etching with Zn metal powder and 2M HCl diluted in deionized water. The substrates were then cleaned by ultrasonication with detergent, rinsed with deionized water, acetone and ethanol, and dried with clean, dry air. A 30-nm-thick TiO₂ compact layer was then deposited on the substrates by an atomic layer deposition system (Savannah 5300, Cambridge Nanotech Inc.) using titanium isopropoxide (TTIP) and water as precursors. The mesoporous TiO₂ layer composed of 20-nm-sized particles was deposited by spin coating at 4500 rpm for 30 s using a hydrothermal-synthesized TiO₂ paste diluted in ethanol (1:4, weight ratio). After drying at 125° C., the TiO₂ films were gradually heated to 500° C., baked at this temperature for 15 min and cooled to room temperature. After cooling to room temperature (25° C.), the substrates were treated in an 0.02M aqueous solution of TiCl₄ for 30 min at 70° C., rinsed with deionized water and dried at 500° C. for 20 min. Prior to their use, the films were again dried at 500° C. for 30 min.

CH₃NH₃SnI₃₋ₓBrₓ was dissolved in N,N-dimethylformamide at a weight concentration of 30% under stirring at 70° C. The solution was kept at 70° C. during the whole procedure. The mesoporous TiO₂ films were then infiltrated with CH₃NH₃SnI₃₋ₓBrₓ by spin coating at 4000 rpm for 45 s and dried at 125° C. for 30 min to remove the solvent. The HTM was then deposited by spin coating at 4000 rpm for 30 s. The spin-coating formulation was prepared by dissolving 72.3 mg (2,2′,7,7′-tetrakis(N,N-di-p-methoxyphenylamine)-9,9-spirobifluorene) (spiro-MeOTAD), 23.3 μl lutidine, 17.5 μl of a stock solution of 520 mg ml⁻¹ lithium bis(trifluoromethylsulphonyl)imide in acetonitrile in 1 ml chlorobenzene. Finally, 100 nm of gold was thermally evaporated on top of the device to form the back contact. The devices were sealed in nitrogen using a 30-um-thick hot-melting polymer and a microscope cover slip to prevent the oxidation.

Device Characterization.

J-V characteristics were measured under AM1.5G light (100 mW cm⁻²) using the xenon arc lamp of a Spectra-Nova Class A solar simulator. Light intensity was calibrated using an NREL-certified monocrystalline Si diode coupled to a KG3 filter to bring spectral mismatch to unity. A Keithley 2400 source meter was used for electrical characterization. The active area of all devices was 10 mm², and an 8 mm² aperture mask was placed on top of cells during all measurements. Incident-photon-conversion-efficiencies (IPCEs) were characterized using an Oriel model QE-PV-SI instrument equipped with a NIST-certified Si diode. Monochromatic light was generated from an Oriel 300 W lamp.

### REFERENCES

1 Bisquert, J. PHOTOVOLTAICS The two sides of solar energy. Nat. Photonics 2, 648-649 (2008).
2 Chung, I., Lee, B., He, J. Q., Chang, R. P. H. & Kanatzidis, M. G. All-solid-state dye-sensitized solar cells with high efficiency. Nature 485, 486-U494 (2012).
3 Kojima, A., Teshima, K., Shirai, Y. & Miyasaka, T. Organometal Halide Perovskites as Visible-Light Sensitizers for Photovoltaic Cells. J. Am. Chem. Soc. 131, 6050-6051 (2009).
4 Etgar, L. et al. Mesoscopic CH₃NH₃PbI₃/TiO₂ Heterojunction Solar Cells. J. Am. Chem. Soc. 134, 17396-17399 (2012).
5 Kim, H. S. et al. Lead Iodide Perovskite Sensitized All-Solid-State Submicron Thin Film Mesoscopic Solar Cell with Efficiency Exceeding 9%. Sci. Rep.2, 591 (2012).
6 Heo, J. H. et al. Efficient inorganic-organic hybrid heterojunction solar cells containing perovskite compound and polymeric hole conductors. Nat. Photonics 7, 487-492 (2013).
7 Liu, M. Z., Johnston, M. B. & Snaith, H. J. Efficient planar heterojunction perovskite solar cells by vapour deposition. Nature 501, 395-398 (2013).
8 Burschka, J. et al. Sequential deposition as a route to high-performance perovskite-sensitized solar cells. Nature 499, 316-319 (2013).
9 Kim, H. S. et al. High Efficiency Solid-State Sensitized Solar Cell-Based on Submicrometer Rutile TiO₂ Nanorod and CH₃NH₃PbI₃ Perovskite Sensitizer. Nano Lett. 13, 2412-2417 (2013).
10 Abrusci, A. et al. High-Performance Perovskite-Polymer Hybrid Solar Cells via Electronic Coupling with Fullerene Monolayers. Nano Lett. 13, 3124-3128 (2013).
11 Edri, E., Kirmayer, S., Cahen, D. & Hodes, G. High Open-Circuit Voltage Solar Cells Based on Organic-Inorganic Lead Bromide Perovskite. J. Phys. Chem. Lett. 4, 897-902 (2013).
12 Bi, D. Q., Yang, L., Boschloo, G., Hagfeldt, A. & Johansson, E. M. J. Effect of Different Hole Transport Materials on Recombination in CH₃NH₃PbI₃ Perovskite-Sensitized Mesoscopic Solar Cells. J. Phys. Chem. Lett. 4, 1532-1536 (2013).
13 Ball, J. M., Lee, M. M., Hey, A. & Snaith, H. J. Low-temperature processed meso-superstructured to thin-film perovskite solar cells. Energy Environ. Sci. 6, 1739-1743 (2013).
14 Abu Laban, W. & Etgar, L. Depleted hole conductor-free lead halide iodide heterojunction solar cells. Energy & Environ. Sci. 6, 3249-3253 (2013).
15 Borriello, I., Cantele, G. & Ninno, D. Ab initio investigation of hybrid organic-inorganic perovskites based on tin halides. Phys. Rev. B 77, 235214 (2008).
16 Mitzi, D. B. Synthesis, structure, and properties of organic-inorganic perovskites and related materials. Prog. Inorg. Chem. 48, 1-121 (1999).
17 Kagan, C. R., Mitzi, D. B. & Dimitrakopoulos, C. D. Organic-inorganic hybrid materials as semiconducting channels in thin-film field-effect transistors. Science 286, 945-947 (1999).
18 Lee, M. M., Teuscher, J., Miyasaka, T., Murakami, T. N. & Snaith, H. J. Efficient Hybrid Solar Cells Based on Meso-Superstructured Organometal Halide Perovskites. Science 338, 643-647 (2012).
19 Snaith, H. J. Perovskites: The Emergence of a New Era for Low-Cost, High-Efficiency Solar Cells. J. Phys. Chem. Lett. 4, 3623-3630 (2013).
20 Park, N. G. Organometal Perovskite Light Absorbers Toward a 20% Efficiency Low-Cost Solid-State Mesoscopic Solar Cell. J. Phys. Chem. Lett. 4, 2423-2429 (2013).
21 Hodes, G. Perovskite-Based Solar Cells. Science 342, 317-318 (2013).
22 Bisquert, J. The Swift Surge of Perovskite Photovoltaics. J. Phys. Chem. Lett. 4, 2597-2598 (2013).
23 Stoumpos, C. C., Malliakas, C. D. & Kanatzidis, M. G. Semiconducting Tin and Lead Iodide Perovskites with Organic Cations: Phase Transitions, High Mobilities, and Near-Infrared Photoluminescent Properties. Inorg. Chem. 52, 9019-9038 (2013).
24 Xing, G. C. et al. Long-Range Balanced Electron- and Hole-Transport Lengths in Organic-Inorganic CH₃NH₃PbI₃. Science 342, 344-347 (2013).
25 Stranks, S. D. et al. Electron-Hole Diffusion Lengths Exceeding 1 Micrometer in an Organometal Trihalide Perovskite Absorber. Science 342, 341-344 (2013).
26 Umari, P., Mosconi, E. & Angelis, F. D. Relativistic Solar Cells. arXiv:1309.4895v1 (2013).
27 Gate, L. F. Comparison of Photon Diffusion-Model and Kubelka-Munk Equation with Exact Solution of Radiative Transport-Equation. Appl. Optics 13, 236-238 (1974).
28 S. Rein, Lifetime spectroscopy: A method of defect characterization in silicon for photovoltaic applications (Springer, Berlin, Germany, 2004).
29 Takahashi, Y., Hasegawa, H., Takahashi, Y. & Inabe, T. Hall mobility in tin iodide perovskite CH₃NH₃SnI₃: Evidence for a doped semiconductor. J. Solid State Chem. 205, 39-43 (2013).
30 Ito, S. et al. Fabrication of thin film dye sensitized solar cells with solar to electric power conversion efficiency over 10%. Thin Solid Films 516, 4613-4619 (2008).
31 Bach, U. et al. Solid-state dye-sensitized mesoporous TiO₂ solar cells with high photon-to-electron conversion efficiencies. Nature 395, 583-585 (1998).
32 Kim, H. S. et al. Mechanism of carrier accumulation in perovskite thin-absorber solar cells. Nat. Commun. 4, 2242 (2013).
33 Noh, J. H., Im, S. H., Heo, J. H., Mandal, T. N. & Seok, S. I. Chemical Management for Colorful, Efficient, and Stable Inorganic-Organic Hybrid Nanostructured Solar Cells. Nano Lett. 13, 1764-1769 (2013).

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean “one or more”.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A photovoltaic cell comprising:
(a) a first electrode comprising an electrically conductive material;
(b) a second electrode comprising an electrically conductive material;
(c) a photoactive material disposed between, and in electrical communication with, the first and second electrodes, the photoactive material comprising a tin halide perovskite compound having the formula ASnX₃, wherein A is a monovalent organic cation and X represents one or more halides; and
(d) a hole transporting material disposed between the first and second electrodes and configured to facilitate the transport of holes generated in the photoactive material to one of the first and second electrodes.

2. The photovoltaic cell of claim 1, wherein the X represents Br, I, or a combination thereof.

3. The photovoltaic cell of claim 2 having a power conversion efficiency under simulated full sunlight of 100 mW cm⁻² of at least 4%.

4. The photovoltaic cell of claim 1, wherein A is an alkylammonium.

5. The photovoltaic cell of claim 1, wherein the tin halide perovskite has the formula ASnI₍₃₋ₓ₎Br₍ₓ₎, wherein 0<x<3.

6. The photovoltaic cell of claim 2 having a power conversion efficiency under simulated full sunlight of 100 mW cm⁻² of at least 5%.

7. The photovoltaic cell of claim 1, wherein the photoactive material comprises a solid solution tin halide perovskite compounds having the formula ASnI₍₃₋ₓ₎Br₍ₓ₎, wherein 0<x<3.

8. The photovoltaic cell of claim 7, wherein the photoactive material has an absorbance of at least 60% in the wavelength range from 600 nm to 800 nm.

9. The photovoltaic cell of claim 7, wherein A is methylammonium.

10. The photovoltaic cell of claim 1, wherein the hole transport material comprises a triarylamine derivative.

11. The photovoltaic cell of claim 10, wherein the hole transport material is doped with a pyridine derivative.

12. The photovoltaic cell of claim 1, wherein the hole transport material is doped with a pyridine derivative.

13. The photovoltaic cell of claim 12, wherein the pyridine derivative is 2,6-lutidine.

14. The photovoltaic cell of claim 12, wherein the pyridine derivative is selected from 2,6-dialkyl derivatives and benzo-substituted pyridines.

15. The photovoltaic cell of claim 12, wherein the hole transport material comprises (2,2′,7,7′-tetrakis(N,N-di-p-methoxyphenylamine)-9,9-spirobifluorene).

16. The photovoltaic cell of claim 12, wherein the X represents Br, I, or a combination thereof.

17. The photovoltaic cell of claim 16, wherein A is an alkylammonium.

18. The photovoltaic cell of claim 5, wherein the hole transport material is doped with a pyridine derivative.

19. The photovoltaic cell of claim 18, wherein the pyridine derivative is 2,6-lutidine.

20. The photovoltaic cell of claim 18, wherein the pyridine derivative is selected from 2,6-dialkyl derivatives and benzo-substituted pyridines.
